(19) United States
(12) Patent Application Publication
(10) Pub. No.: US 2026/0314311 A1
(43) Pub. Date: Oct. 8, 2026

(54) WAFER TRANSFER BLADE AND ASSEMBLY

(71) Applicant: Taiwan Semiconductor Manufacturing Company Limited, Hsin-Chu (TW)

(72) Inventors: Yen-Hsiang CHEN, New Taipei City (TW); Hung-Chih WANG, Taichung City (TW); Jia-Wei TSENG, Hsinchu City (TW); Yuan-Hsin CHI, Taichung County (TW); Sheng-Yuan LIN, Hsinchu (TW)

(21) Appl. No.: 19/170,167

(22) Filed: Apr. 4, 2025

(51) Int. Cl. H01L 21/673; B65G 47/90; H01L 21/677

(52) U.S. Cl. CPC H10P 72/18; B65G 47/90; H10P 72/3306

(57) ABSTRACT

Among other things, a wafer transfer blade is provided. The wafer transfer blade has a bottom exterior and a top exterior opposite the bottom exterior. The bottom exterior has a support configuration disposed between a front structure and a rear structure that extend above the support configuration. The support configuration has a front portion adjoining the front structure and a rear portion adjoining the rear structure. The rear portion has a slide having a top surface that extends downwardly from a front joint located toward the front structure to a rear joint located toward the rear structure.

### BACKGROUND

Semiconductor devices are formed on, in, and/or from semiconductor wafers, and are used in a multitude of electronic devices, such as mobile phones, laptops, desktops, tablets, watches, gaming systems, and various other industrial, commercial, and consumer electronics. In a semiconductor manufacturing facility, systems are used to process semiconductor wafers and wafers are moved between these systems.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 shows an illustration of wafers on wafer transfer blades, with one of the wafers being warped;

FIG. 2 shows an illustration of wafers being held in carriers, with one of the carriers holding wafers that are warped;

FIG. 3 shows an illustration of a wafer processing system in which a transfer module may operate, in accordance with some embodiments;

FIG. 4 shows an illustration of a top view of a wafer transfer tool, in accordance with some embodiments;

FIG. 5 shows an illustration of a side view of a wafer transfer tool, in accordance with some embodiments;

FIG. 6 show an illustration of a side view of a wafer transfer blade of a wafer transfer tool supporting a warped wafer, in accordance with some embodiments;

FIG. 7 shows an illustration of a side view of a support configuration of a wafer transfer blade supporting a warped wafer, in accordance with some embodiments;

FIG. 8 shows an illustration of a top view of a warped wafer;

FIG. 9 shows an illustration of a side view of a slide of a wafer transfer blade, in accordance with some embodiments;

FIG. 10 shows an illustration of a side view of a slide of a wafer transfer blade, in accordance with some embodiments;

FIG. 11 shows an illustration of a top view of a wafer transfer blade, in accordance with some embodiments;

FIG. 12 shows an illustration of a top view of a wafer transfer blade, in accordance with some embodiments;

FIG. 13 shows an illustration of a top view of a portion of a transfer module in a main frame, in accordance with some embodiments;

FIG. 14 shows an illustration of a side view of a portion of a transfer module in a main frame, in accordance with some embodiments;

FIG. 15 shows an illustration of a top view of a wafer transfer blade of a wafer transfer tool in a retracted position in a portion of a transfer module, in accordance with some embodiments;

FIG. 16 shows an illustration of a side view of a wafer transfer tool in a portion of a transfer module, in accordance with some embodiments;

FIG. 17 shows an illustration of a top view of a wafer transfer blade in a retracted position, supporting a warped wafer in a portion of a transfer module, in accordance with some embodiments;

FIG. 18 shows an illustration of a top view of a wafer transfer blade in an extended position, supporting a warped wafer in a portion of a transfer module, in accordance with some embodiments;

FIG. 19 shows an illustration of a side view of a wafer transfer blade supported on a wafer holder, wherein a warped wafer has been lifted off the wafer transfer blade by lifts pins of the wafer holder, in accordance with some embodiments;

FIG. 20 shows an illustration of a top view of a wafer transfer blade in a retracted position, supporting a warped wafer in a portion of a transfer module having a position sensor assembly, in accordance with some embodiments;

FIG. 21 shows an illustration of an end view of a position sensor of a position sensor assembly, wherein a light beam passes unimpeded from an emitter to a receiver, in accordance with some embodiments;

FIG. 22 shows an illustration of an end view of a position sensor of a position sensor assembly, wherein a light beam is partially blocked by a bar of a wafer transfer blade when the wafer transfer blade is in a normal position, in accordance with some embodiments;

FIG. 23 shows an illustration of an end view of a position sensor of a position sensor assembly, wherein a light beam is partially blocked by a bar of a wafer transfer blade when the wafer transfer blade is not in a normal position, in accordance with some embodiments;

FIG. 24 shows a flow diagram illustrating a first portion of a method of moving a wafer using a wafer transfer blade, in accordance with some embodiments; and

FIG. 25 shows a flow diagram illustrating a second portion of a method of moving a wafer using a wafer transfer blade, in accordance with some embodiments

### DETAILED DESCRIPTION

The following disclosure provides several different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact and may also include embodiments in which additional features may be formed between the first and second features, such that the first and second features may not be in direct contact. In addition, the present disclosure may repeat reference numerals or letters in the various examples. This repetition is for the purpose of simplicity and clarity and does not in itself dictate a relationship between the various embodiments or configurations discussed.

Further, spatially relative terms, such as “beneath,” “below,” “lower,” “above,” “upper” and the like, may be used herein for ease of description to describe one element or feature's relationship to other element(s) or feature(s) as illustrated in the figures. The spatially relative terms are intended to encompass different orientations of the device in use or operation in addition to the orientation illustrated in the figures. The apparatus may be otherwise oriented (rotated 90 degrees or at other orientations) and the spatially relative descriptors used herein may likewise be interpreted accordingly.

In a semiconductor manufacturing facility (FAB), there are a number of highly specialized and automated systems or tools for processing semiconductor wafers. These tools may be arranged in stations where one or more processes are performed. The semiconductor wafers are moved into, within, and between these stations. Some of this movement may be performed using carriers that hold a number of wafers. Carriers may be used to move wafers to and between stations. An example of a carrier may be a cassette having a plurality of slots for holding wafers in a horizontal orientation. These slots may be arranged vertically in one or more columns.

At a station where processing is to occur, a transfer module may remove individual wafers from a carrier, such as a cassette, using a wafer transfer blade moved by the transfer module. The automated handler moves the wafer transfer blade such that the wafer remains horizontal on the wafer transfer blade as the wafer is moved from the carrier to processing apparatus at the station. In this manner, the wafer is maintained in its position on the wafer transfer blade primarily through the operation of gravity.

Some tools may be arranged in a group, which may be referred to as a cluster tool. A cluster tool may be housed in a station having a plurality of chambers. Such a station may be referred to as a mainframe. Each of the chambers in a mainframe may contain a tool. The chambers may adjoin a transfer space or corridor, within which a transfer module may be movably disposed. The transfer module may move a wafer from a carrier to a chamber and from one chamber to another chamber. The transfer module may also use a movable wafer transfer blade to move the wafer from one location to another.

During the transfer of a wafer between a carrier and a station or chamber or between chambers, the wafer may, on occasion, shift out of position on the wafer transfer blade, especially if the wafer transfer blade is rotated quickly. Such a shift may cause the wafer to become “lost on the blade”, which may adversely affect the transfer of the wafer between locations. A number of factors may contribute to the shifting of a wafer. One such factor that may contribute to shifting of a wafer is warpage of the wafer. Warpage may cause the backside of a wafer to have less contact area with a top surface area of the wafer transfer blade, thereby reducing frictional holding forces between the wafer and the wafer transfer blade, which may be sufficient to allow shifting to occur.

Warpage of a wafer may also adversely affect the transfer of wafers onto and off of a wafer transfer blade due to the increase in vertical space occupied by the wafer, such as in a carrier, as will be described more fully below.

Wafer warpage may occur when one or more layers are deposited on a substrate due to intrinsic stresses and the coefficient of thermal expansion (CTE) mismatch of the layers and the substrate.

Some types of wafers are more prone to warpage than other types of wafers. For example, gallium nitride (GaN) on Silicon (Si) wafers tend to be prone to warpage. A GaN layer may be deposited on a Si substrate by epitaxial crystal growth, such as by a metal-organic vapor phase epitaxy (MOVPE) deposition of c-plane GaN on a (111) Si substrate. The CTE of the GaN layer is significantly larger than the CTE of the Si, resulting in a mismatch that may be up to more than 50%. This large CTE mismatch, together with the lattice mismatch between the GaN layer and the Si substrate can lead to significant warpage of a GaN on a Si substrate.

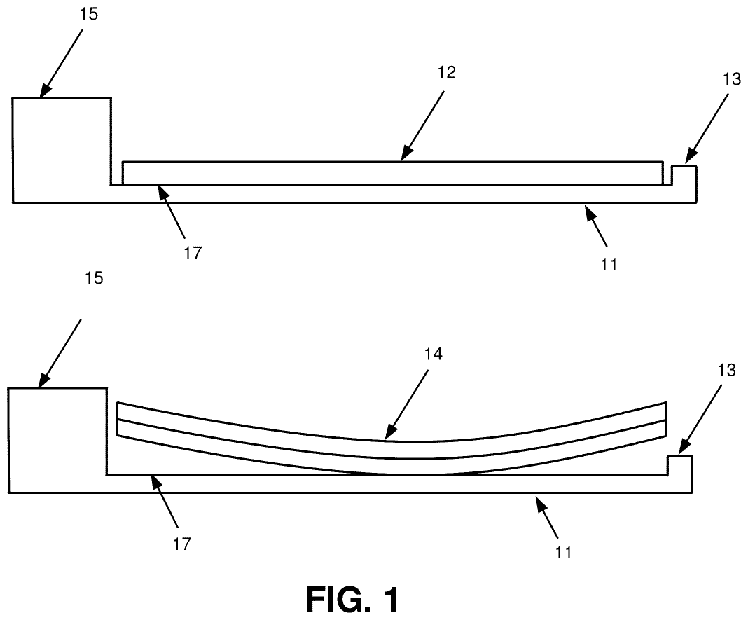

FIG. 1 shows a wafer transfer blade 11 supporting a metal-oxide-semiconductor (CMOS) wafer 12 and another wafer transfer blade 11 supporting a wafer 14, which may be a GaN on Si wafer. The wafer transfer blade 11 has front and rear structures 13, 15. The front structure 13 is located at a free end of the wafer transfer blade 11, while the rear structure 15 is located at a mounting end of the wafer transfer blade 11. As shown, the CMOS wafer 12 is not warped. As such, the CMOS wafer 12 is bracketed by the front and rear structures 13, 15 and its bottom surface is fully supported on a planar holding surface 17 of the wafer transfer blade 11. In contrast, the wafer 14 is warped and its outer portions are not supported on the holding surface 17; merely a center portion of the wafer 14 is supported on the holding surface 17 of the wafer transfer blade 11. In addition, a front outer portion of wafer 14 is disposed above the front structure 13, which results in the wafer 14 not being fully bracketed by the front and rear structures 13, 15. As a result, the wafer 14 is not supported in a stable manner and is susceptible to shifting.

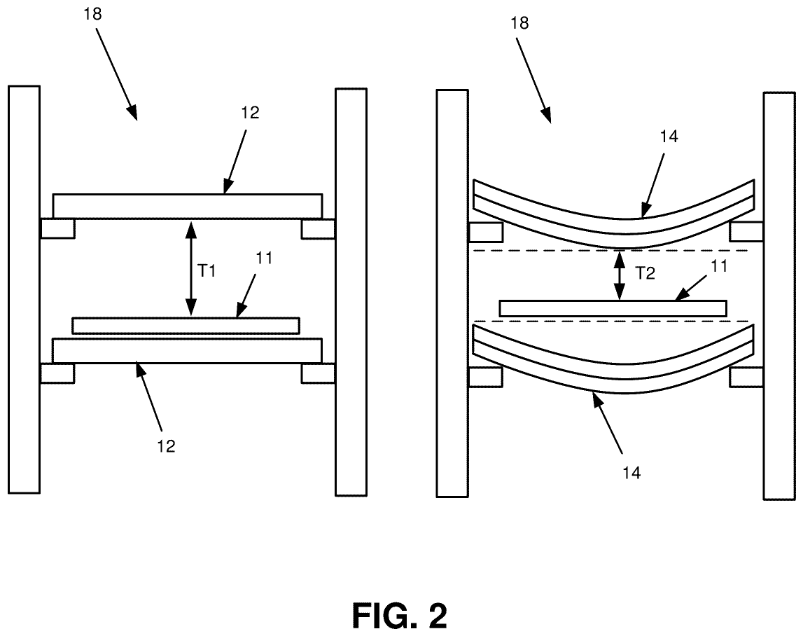

In addition to making the wafer 14 susceptible to shifting, the warpage of the wafer 14 also complicates the transfer of the wafer 14 between locations using the wafer transfer blade 11. For example, the warpage of the wafer 14 increases the vertical space occupied by the wafer in a holding area, such as in a carrier, which decreases the space within which the wafer transfer blade 11 is maneuvered to engage the wafer 14 to properly position the wafer 14 on the wafer transfer blade 11. This decreased space or reduced tolerance increases the risk that the wafer 14 or an adjacent wafer may be damaged by the wafer transfer blade 11 when the wafer transfer blade 11 is used to access the wafer 14 in the holding area. This reduced tolerance is illustrated in FIG. 2. As shown, when the wafer 14 is disposed in a carrier 18, the tolerance T2 for proper insertion of the wafer transfer blade 11 into the carrier 18 to remove the wafer 14 is significantly smaller than the tolerance T1 for proper insertion of the wafer transfer blade 11 into the carrier 18 to remove the CMOS wafer 12.

To mitigate shifting of the wafer on the wafer transfer blade caused by wafer warpage or otherwise, one or more clamping devices may be used to hold the wafer on the wafer transfer blade. In addition to, or in lieu of clamping device(s), one or more elastic pads may be mounted to the wafer transfer blade to increase frictional holding forces between the wafer and the wafer transfer blade. These shift-inhibiting features are useful for wafer transfer applications where the wafers are not overly fragile. According to some embodiments, at least one of a wafer transfer blade, an apparatus for moving a wafer, or a method of moving a wafer is provided. Such may be used regardless of whether a wafer is fragile, such as a GaN on Si wafer. For example, structure(s), technique(s), etc. provided herein accommodate warpage and/or other characteristics of fragile (e.g., GaN on Si) wafers.

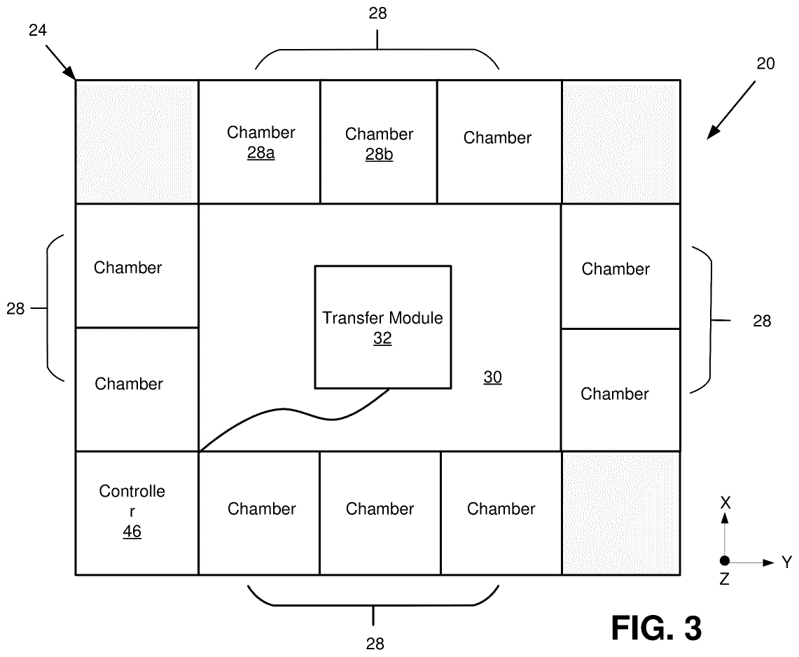

FIG. 3 is a schematic illustration of a wafer processing system 20 in which a transfer assembly or module 32 may operate, in accordance with some embodiments. The wafer processing system 20 may comprise a cluster tool housed in a main frame 24. The main frame 24 may include a plurality of chambers 28 disposed around one or more sides of a transfer space 30. In some embodiments, the chambers 28 may be arranged in a rectangle around the transfer space 30 and may include multiple levels. In such embodiments, the transfer space 30 may have a rectangular shape. In some embodiments, the chambers 28 may be arranged in two rows of one more levels, with the transfer space 30 extending between the rows, such as a corridor. In some embodiments, the chambers may be arranged in a single row of one or more levels and the transfer space 30 may run parallel to the row.

One of the chambers 28 may be a transfer chamber 28 configured for transferring wafers to and from other areas of the FAB. For example, such a transfer chamber 28 may function as a docking location where a carrier, such as the carrier 18 may be accessed by the transfer module 32. Other chambers 28 may house tools for processing wafers. For example, the other chambers 28 may include tools for cleaning, deposition, lithography, etching, polishing, and/or performing other processes.

The transfer module 32 is disposed in the transfer space 30 and is movable so as access the chambers 28. The transfer module 32 may be operable to move in an X-direction, a Y-direction, a Z-direction and an angular direction θ. The transfer module 32 includes a wafer transfer tool 40 connected to a moveable arm or shuttle. The wafer transfer tool 40 is configured to carry a warped semiconductor wafer, such as a wafer 42. The wafer 42 may be a GaN on Si wafer, or another type of wafer. The transfer module 32 is configured to move the wafer 42 from one location to another, such as from one chamber 28 to another chamber 28. The transfer module 32 is connected, either wirelessly or by hardwire connection, to a controller 46.

The controller 46 is configured to control the transfer module 32 to, inter alia, move the wafer 42 pursuant to predetermined operating procedures or routines. The controller 46 includes memory for storing computer executable code for performing the predetermined operating routines, and one or more computer processors for executing the code. The predetermined operating routines performed by the transfer module 32 may, by way of example, include removing the wafer 42 from a carrier 18 in the transfer chamber 28a and transferring the wafer 42 to a tool in another chamber 28b, where a first process is performed on the wafer 42. This first process may, by way of example, be a chemical vapor deposition (CVD) process and the chamber 28b may be referred to as a deposition chamber 28b. After the CVD process is complete, such as may be determined from a signal received from the deposition tool, the transfer module 32 may then remove the wafer 42 from the deposition tool in the deposition chamber 28b and transfer the wafer 42 to a tool in another chamber 28 or elsewhere.

As a part of the above-described routine, the controller 46 may control the transfer module 32 to move the wafer transfer tool 40 in a precise manner when removing the wafer 42 from the carrier 18 in the transfer chamber 28a and moving the wafer 42 to the deposition tool in the deposition chamber 28b. For example, the controller 46 may control transfer module 32 to move the wafer transfer tool 40 to position the wafer 42 on top of a wafer holder in the deposition chamber 28b. The controller 46 may also control the transfer module 32 to move the wafer transfer tool 40 in a precise manner when inserting the wafer 42 into a carrier 18 in the transfer chamber 28a, or removing the wafer 42 from the wafer holder in the deposition chamber 28b and/or otherwise moving the wafer 42 into and out of other chambers 28.

In addition to being operatively connected to the transfer module 32, the controller 46 may also be operatively connected to the deposition tool in the deposition chamber 28b and other tools in other chambers 28. Alternately or in addition, the controller 46 may be operatively connected to other controllers that control tools in the chambers 28 and/or may be operatively connected to a main facility control system. With such connections, the control of the transfer module 32 may be coordinated with the control of the processes performed on the wafer 42 in the various chambers 28 to and from which the wafer 42 is moved.

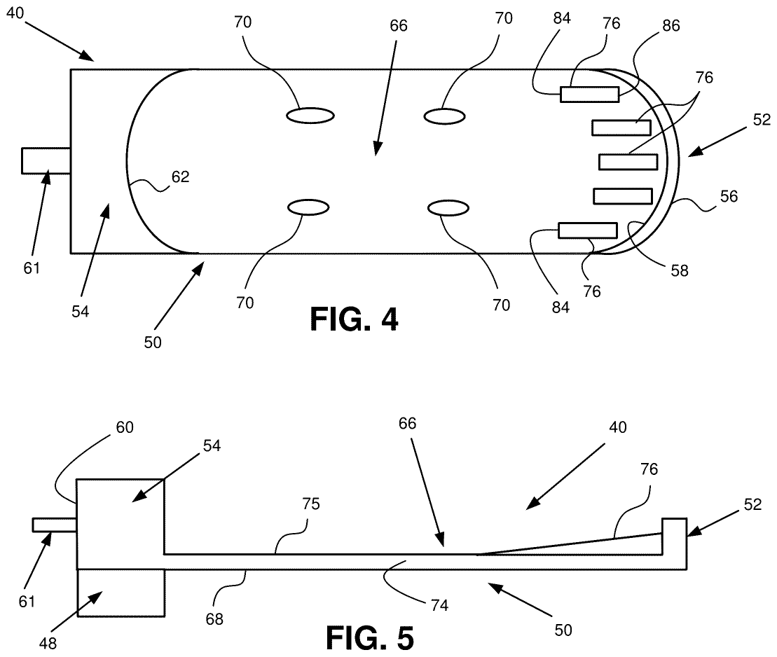

Referring now to FIGS. 4-12, the wafer transfer tool 40 may include a wafer transfer blade 50 releasably secured to a mount 48. In some embodiments, the wafer transfer blade 50 may be a unitary structure and may be formed from a ceramic, a metal, or a polymer. An example of a ceramic that may be used includes sintered alumina ceramic. An example of a metal that may be used includes aluminum. An example of a polymer that may be used includes polytetrafluoroethylene (PTFE). In some embodiments, the wafer transfer blade 50 may have a multi-piece construction.

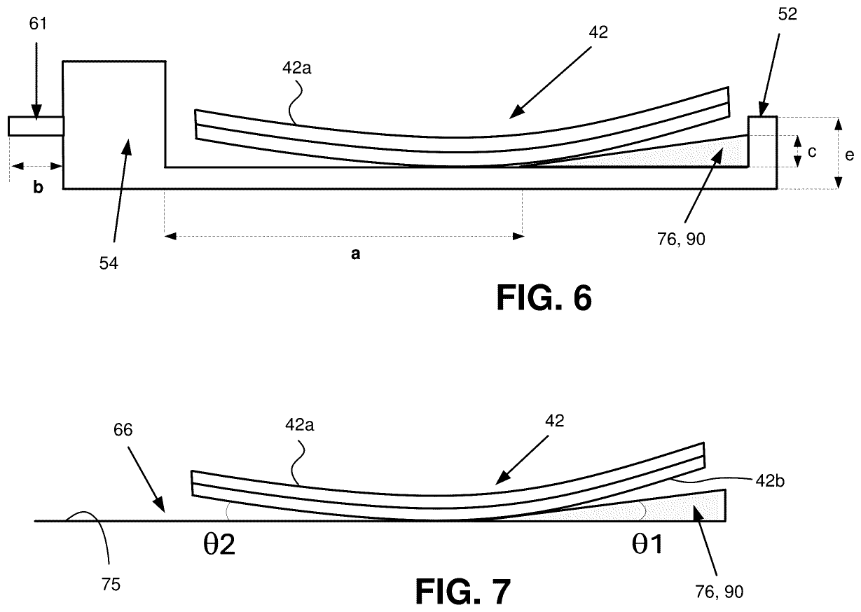

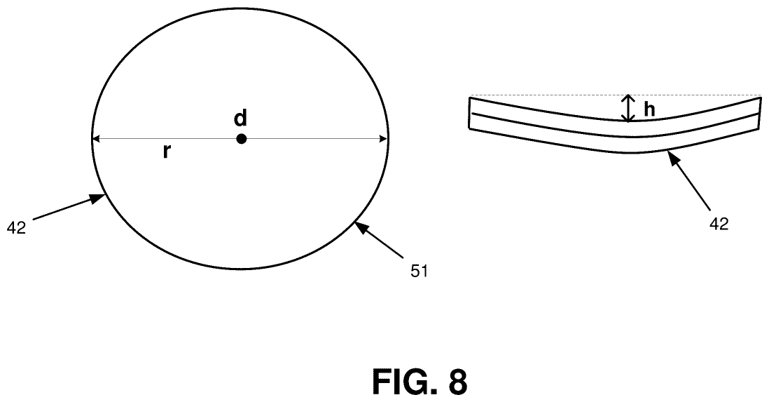

The wafer transfer blade 50 is configured to hold a wafer 42 in a stable manner during its horizontal movement from one location to another by the transfer module 32. Being warped, the wafer 42 may have a parabolic shape with a concave top surface 42a and a convex bottom surface 42b, as shown in FIGS. 6 and 7. In the shown embodiment, the wafer 42 may be a GaN on Si wafer, with the top surface 42a being part of a top layer comprising GaN and the bottom surface 42b being part of a bottom layer comprising Si. The Si layer may have a thickness from about 600 μm to about 1350 μm, while the GaN layer has a thickness of from about 0.1 μm to about 10 μm. The concentration of Gallium (Ga) may be determined by energy-dispersive X-ray spectroscopy (EDX). When viewed from above, as shown in FIG. 8, an outer edge 51 of the wafer 42 may form an ellipse having a major axis with a diameter d and a radius r. When the wafer 42 is placed on a horizontal surface (such as the surface 75), the wafer 42 forms a wafer warpage angle θ2 with the surface, as shown in FIG. 7. The concavity of the top surface 42a may be represented by the height difference h between a center of the top surface 42a and opposing outer edges of the top surface 42a, as shown in FIG. 8. The height difference may be about 10 μm or greater.

The wafer transfer blade 50 may have a free end portion with a front structure 52 and a mounting end portion with a rear structure 54. The front structure 52 may comprise a wall having a curved outer surface 56 and a curved inner surface 58, while the rear structure 54 may have a planar outer surface 60 and a curved inner surface 62. A bar 61 is secured to the rear structure 54 and extends rearwardly therefrom. The bar 61 may extend from the outer surface 60 or may extend from a mount on a top surface of the rear structure 54. In some embodiments, the bar 61 may have a length of greater than 0.1 mm. The wafer transfer blade 50 may have a support configuration 66 between the front structure 52 and the rear structure 54, while a planar bottom surface 68 may extend the length of the wafer transfer blade 50 between and including the front structure 52 and the rear structure 54. One or more openings 70 may extend through the wafer transfer blade 50, between and through the support configuration 66 and the bottom surface 68. In some embodiments, such as that shown, there may be a plurality of openings 70 (e.g., four) and the openings 70 may be elliptical. When the wafer transfer blade 50 is used to move a wafer 42 to a chamber 28, lift pins of a wafer holder in the chamber 28 may be passed through the openings 70 to lift the wafer 42 off of the wafer transfer blade 50. The wafer transfer blade 50 may also have side surfaces that extend the length of the wafer transfer blade 50 between and including the front structure 52 and the rear structure 54.

The support configuration 66 may have a topography that is partially planar and partially contoured by one or more slides 76. For example, the support configuration 66 may have a planar surface 75 that extends from the rear structure 54 to at least the slide(s) 76. In some embodiments, the surface 75 may extend all the way to the front structure 52 and the slide(s) 76 may be disposed on the surface 75. The front structure 52 extends above the surface 75 by a height e, as shown in FIG. 6.

The support configuration 66 includes the one or more slides 76, which are disposed toward the front structure 52. In some embodiments where the wafer transfer blade 50 is a monolithic structure, the slide(s) 76 may have the same composition as the rest of the wafer transfer blade 50. For example, if the rest of the wafer transfer blade 50 is formed from PTFE, the slide(s) 76 will be formed from PTFE. In some embodiments where the wafer transfer blade 50 is not monolithic, the slide(s) 76 may be formed from a different material than the rest of the wafer transfer blade 50. For example, if the rest of the wafer transfer blade 50 is formed from ceramic, the slide(s) 76 may be formed from PTFE or metal.

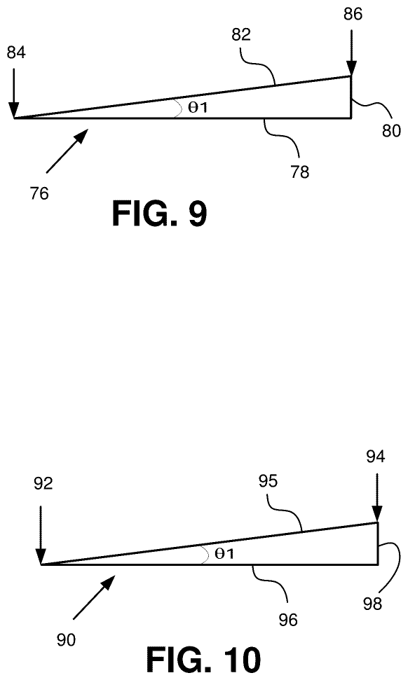

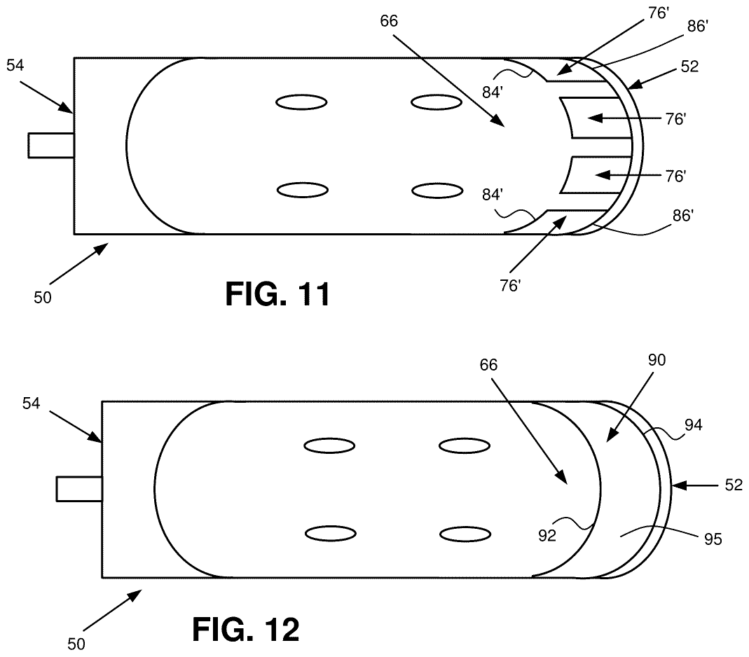

In some embodiments, the support configuration 66 comprises a plurality of the slides 76. The number of slides 76 may be two or more, up to a number where the slides 76 approximate a single slide, such as the slide 90 described below. As shown in FIG. 9, each of the slides 76 may have a generally wedge-shaped configuration, with a planar bottom 78 joined to an end 80 at about a right angle. A top surface 82 is joined to the bottom 78 at a rear joint 84 at a slide angle θ1 (e.g., an acute angle), and is joined to the end 80 at a front joint 86. The top surface 82 may be planar or slightly curved. The top surface 82 extends (e.g., slopes, curves, etc.) downwardly from the front joint 86 to the rear joint 84. Some or all of the ends 80 may be configured to conform to the inner surface 58 of the front structure 52, as shown in FIG. 11 where the slide elements are distinguished with a prime. Thus, if the inner surface 58 is curved, some or all of the ends 80′ of the slides 76′ may be curved to conform to and be adjoined to the inner surface 58. The rear joints 84′ of the slides 76′ may also be curved. The lengths of the slides 76, 76′ may be the same or different. The slides 76, 76′ may be shaped and arranged such that the rear joints 84, 84′ form an arc and the front joints 86, 86′ form an arc. In this manner, the slides 76, 76′ may form an interrupted sloping or parabolic arc adjacent to the front structure 52, as shown in FIG. 11.

In some embodiments, an enlarged single slide 90 may be disposed in the support configuration 66, toward the front structure 52, as shown in FIG. 12. The slide 90 is generally arc-shaped and has a curved bottom joint 92, and a curved front joint 94 that conforms to the inner surface 58 of the front structure 52. The front joint 94 is disposed adjacent to the inner surface 58 and, in some embodiments, may adjoin the inner surface 58. As shown in FIG. 10, the slide 90 has a top surface 95 that is joined to a bottom 96 at the bottom joint 92 at the slide angle θ1, and is joined to an end 98 at the front joint 94. The top surface 95 may be continuously sloped or parabolic.

In some embodiments where the slides 76, 90 are part of a monolithic structure forming the wafer transfer blade 50, the bottoms 78, 96 may simply be plane(s) that are coplanar with the surface 75. Similarly, the ends 80, 98 may, in some embodiments, be coterminous with the front wall. In some embodiments where the slides 76, 90 are structures separate from the rest of the wafer transfer blade 50, the bottoms 78, 96 may be surfaces and the ends 80, 98 may be surfaces.

In each of the slides 76, 90 the end 80, 98 has a height c, as shown in FIG. 6. The height e of the front structure 52 may be greater than or equal to the height c of the end 80, 98 (e≥c) to inhibit scratching the bottom surface 42b of the wafer 42 during a transfer of the wafer 42. The slides 76, 90 may be positioned such that the rear joint 84 or the portion of the bottom joint 92 closest to the rear structure 54 is located a distance a from the rear structure 54, wherein the distance a is less than the diameter d of the wafer 42 and greater than the radius r of the wafer 42 (r<a<d). As set forth above, the slides 76 and the slide 90 have slide angles θ1, respectively, and when the wafer 42 is placed on the surface 75, the wafer 42 forms a wafer warpage angle θ2 with the surface, as shown in FIG. 7. In some embodiments, the slide angle θ1 may be greater than the wafer warpage angle θ2 (θ1>θ2).

In some embodiments where the slides 76, 90 are separate pieces, the slides 76, 90 may be secured to the surface 75 by a mechanical mechanism, an adhesive mechanism, a welding mechanism, or a combination thereof. According to some embodiments, top surfaces of one or more slides have common profiles. For example, a top surface of one slide has a first surface profile and a top surface of another slide has a second surface profile matching the first surface profile (e.g., slope, curvature, topology, porosity, coefficient of friction, material composition, etc. alone or in combination), such as to provide, for example, a uniform, monolithic, etc. structure.

The slide(s) 76, 90 provide the support configuration 66 toward the front structure 52 with a contoured surface that more closely conforms to a bottom surface of the wafer 42 than a planar surface. This contoured surface may be sloped or parabolic and may be continuous or interrupted. The contoured surface helps inhibit the wafer 42 from sliding forward, toward the front structure 52 when the transfer module 32 moves the wafer transfer blade 50 with the wafer 42.

It should be appreciated from the foregoing that the wafer transfer blade 50 is configured for carrying a wafer having a particular warpage profile, e.g., the wafer 42. It should be appreciated that in some embodiments, the transfer module 32 may store a plurality of wafer transfer blades configured for different warpage profiles, respectively. For example, the number, dimensions, shapes, placement, etc. of the slides 76 of the wafer transfer blades may differ to accommodate different warpage profiles of wafers. The different wafer transfer blades may be stored in a location accessible by the transfer module 32, such as the transfer chamber 28a. In addition, digital warpage profiles of the wafers for which the different wafer transfer blades are configured may be stored in electronic storage accessible by the controller 46. When a batch of wafers is to be processed, a metrology device may use a laser to scan a representative example of the batch to generate a digital warpage profile of the representative example. The controller 46 may execute a routine to select a transfer blade most appropriate for the representative example by comparing the digital warpage profile of the representative example to the stored digital warpage profiles for the different stored blades and choosing the stored blade having a close digital warpage profile. If the selected wafer transfer blade is different from the current wafer transfer blade, the current wafer transfer blade may be removed from the mount 48 of the wafer transfer tool 40 and then the selected wafer transfer blade may then be attached to the mount 48. The foregoing routine may be performed automatically in a single location (e.g., the transfer chamber 28a) using an automated tool transfer apparatus.

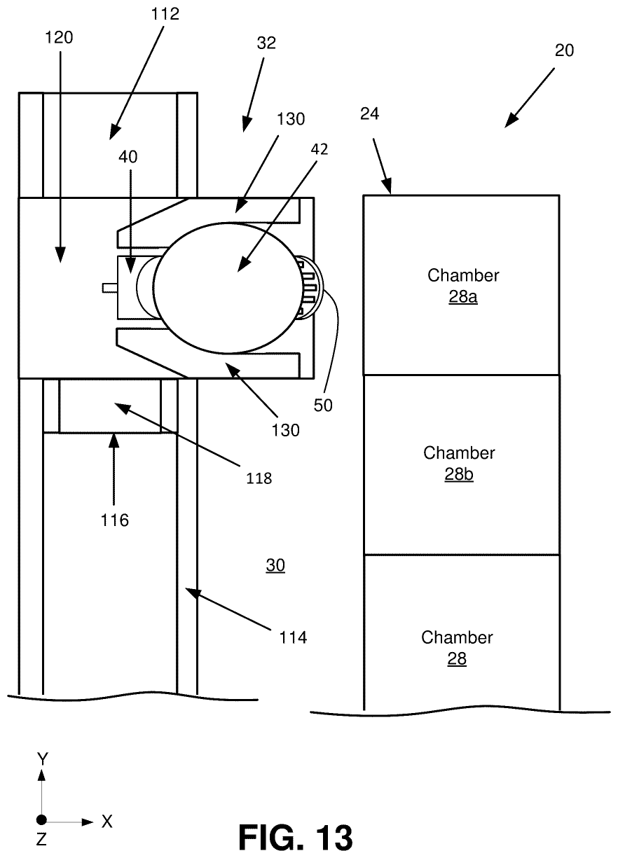

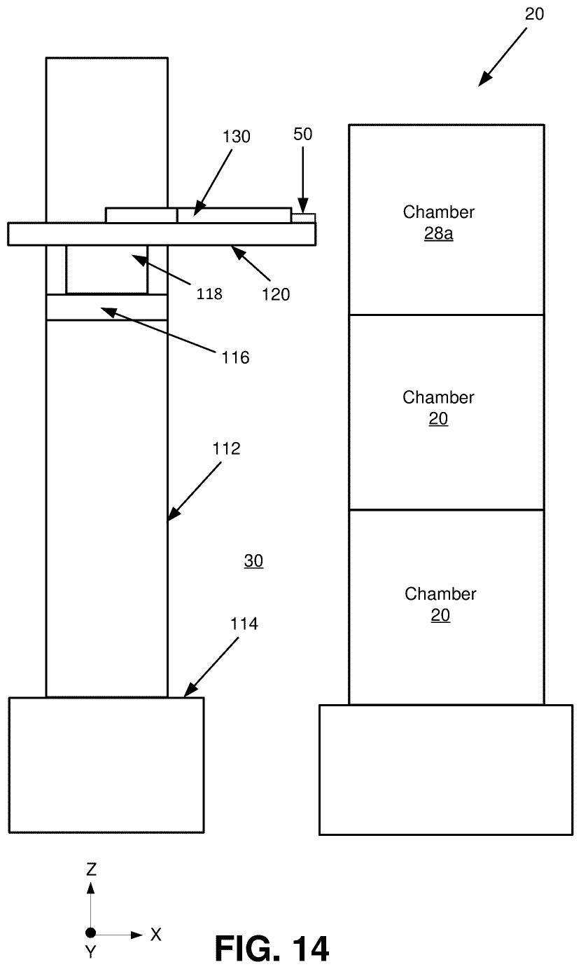

Referring to FIGS. 13, 14, there is shown an embodiment of the transfer module 32. The transfer module 32 is mounted in the transfer space 30 and is movable so as access the chambers 28 in the main frame 24. For example, the transfer module 32 is operable to move the wafer transfer blade 50 to each of the chambers 28 to remove wafers 42 from the chambers 28 and/or insert wafers 42 into the chambers 28. Although only one bank of chambers 28 on one side of the transfer module 32 is shown in FIGS. 13, 14, it should be appreciated that the transfer module 32 may be used with additional chambers 28 located on an opposite side of the transfer module 32 and/or at opposing ends of the transfer module 32, such as is shown in FIG. 3.

The transfer module 32 may include a pedestal 112 mounted to a track 114 so as to be movable in a Y-direction. A platform 116 may be mounted in cantilever fashion to the pedestal 112 so as to be movable in a Z-direction. A rotary support 118 may be mounted to the platform 116 and may be configured to rotatably support a table 120. The rotary support 118 may be operable to move (rotate) the table 120 in an angular direction. The wafer transfer tool 40 is mounted to the table 120 to be movable in an X-direction relative to the table 120. In some embodiments, the mount 48 of the wafer transfer tool 40 may be secured to an arm of a linear actuator and/or a shuttle movably mounted in a track of the table 120, as described more fully below.

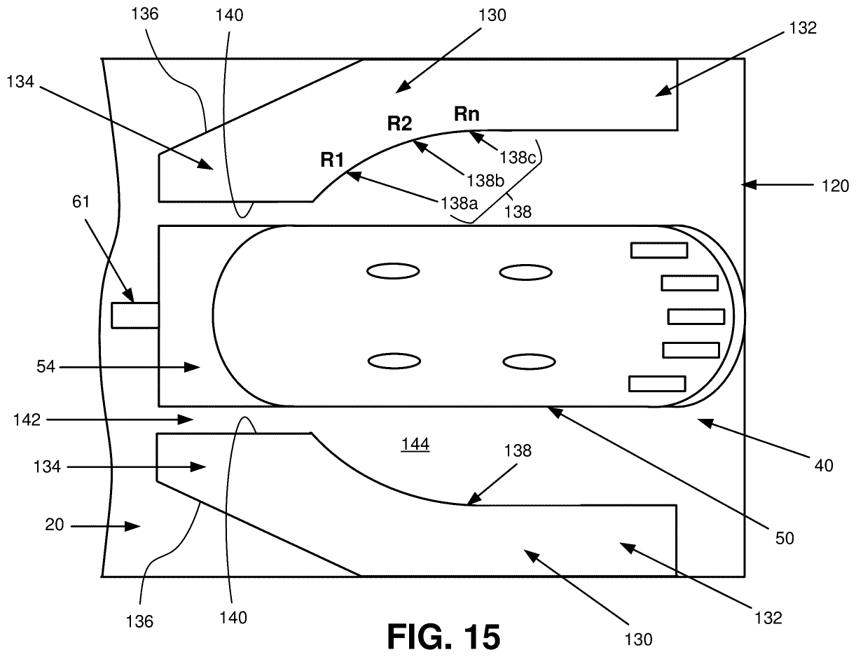

Referring now to FIG. 15, a pair of wafer guides 130 may be secured to the table 120, toward an outer end thereof. Each wafer guide 130 may have a front end portion 132 and a rear end portion 134. The wafer guides 130 may be spaced apart and positioned to receive a wafer 42 in-between. Each wafer guide 130 may include an angular outer edge 136 and a contoured inner edge 138 joined to a linear inner edge 140. The linear inner edges 140 of the wafer guide 130 may be disposed toward the rear end portions 134 and may be joined to the contoured inner edges 138, respectively. The linear edges 140 may be at least substantially parallel to each other and form a rectangular passage 142 therebetween. The contoured inner edges 138 may complement each other to form a partially elliptical holding space 144.

Each contoured inner edge 138 may have three or more sections with three or more different radii of curvature, respectively. The radii of curvature of the sections decrease in the direction from the front end portion 132 to the rear end portion 134. By way of example, the inner edge 138 may include sections 138a,b,c. Section 138a is curved and has a radius of curvature of R1. Section 138b is also curved and has a radius of curvature of R2. Section 138c may be slightly curved and has a radius of curvature of Rn. The radius of curvature Rn is greater than the radius of curvature of R2, which is greater than the radius of curvature R1 (Rn>R2>R1). The different radii of curvature of the sections of the inner edge 138 may correspond to the different radii of curvature of the ellipse formed by the outer edge 51 of the wafer 42 as a result of the warpage of the wafer 42. The different radii of curvature also facilitate the movement of the wafer 42 into the holding space 144.

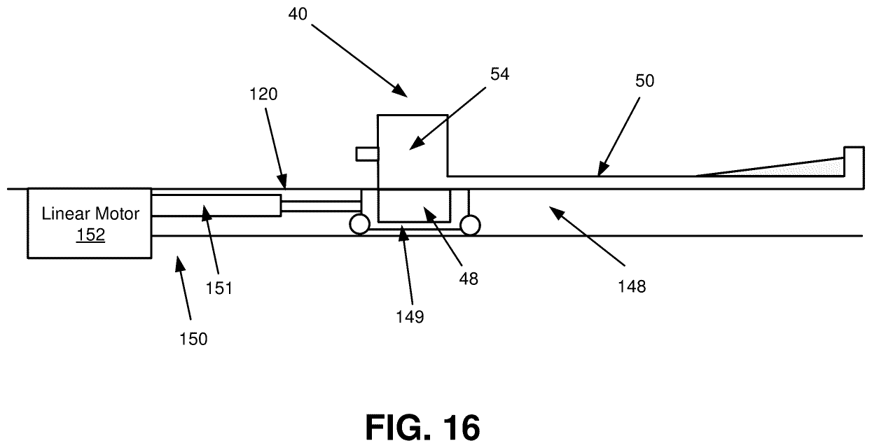

The wafer transfer blade 50 may be movable in the X-direction between a retracted position, wherein the wafer transfer blade 50 is fully disposed on the table 120, and an extended position, wherein the wafer transfer blade 50 is not disposed on the table 120, or is merely partially disposed on the table 120, and may be positioned to engage a wafer 42 in one of chambers 28. In FIG. 15, the wafer transfer blade 50 is shown in the retracted position. As shown, the rear structure 54 is disposed in the passage 142 between the two wafer guides 130. In some embodiments, a track 148 (e.g., shown in FIGS. 16-18) recessed into the table 120 or on top of the table 120 may extend through the passage 142, as well as through the holding space 44 and outwardly therefrom to an end proximate to an edge of the table 120. As shown in FIG. 16, a shuttle 149 may be movably mounted in the track 148 and secured to the mount 48 of the wafer transfer tool 40. The shuttle 149 with the wafer transfer tool 40 mounted thereto may be moved in the track 148 by a linear actuator 150 controlled by the controller 46. In some embodiments, the linear actuator 150 may be directly connected to the mount 48 of the wafer transfer tool 40. The linear actuator 150 may comprise an arm 151 driven by a linear motor 152. The linear actuator 150 may be mounted inside the table 120.

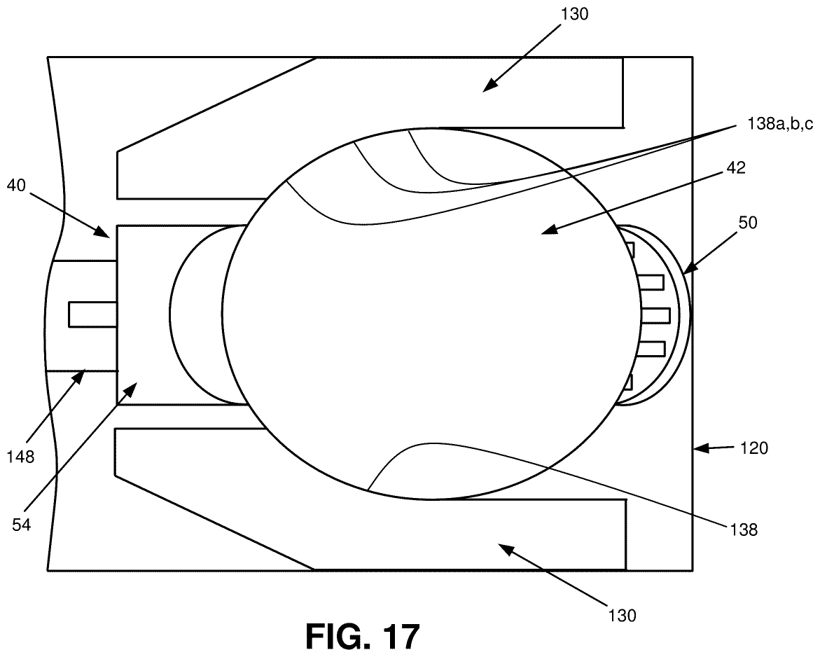

Referring now to FIG. 17, the wafer 42 is shown supported on the wafer transfer blade 50, which is in the retracted position. The wafer 42 is held between the wafer guides 130. The outer edge 51 of the wafer 42 is in contact with (as shown) or in close proximity to the inner edge sections 138a, 138b and at least portions of the inner edge sections 138c of the wafer guides 130. In this manner, the wafer 42 may be in contact with three or more sections of each of the inner edges 138 of the wafer guides 130. In some embodiments, less than half of the outer edge 51 of the wafer 42 is in contact with the inner edges 138 of the wafer guides 130. In other words, the maximum contact of the wafer guides 130 with the wafer 42 is less than or equal to π*r of the wafer 42.

When the wafer 42 is held by the wafer guides 130 in the manner described above, the wafer 42 is properly positioned on the support configuration 66 of the wafer transfer blade 50 so as to not be susceptible to sliding in a longitudinal direction of the wafer transfer blade 50 and is blocked from sliding in a lateral direction of the wafer transfer blade 50, such as when the table 120 is rotated.

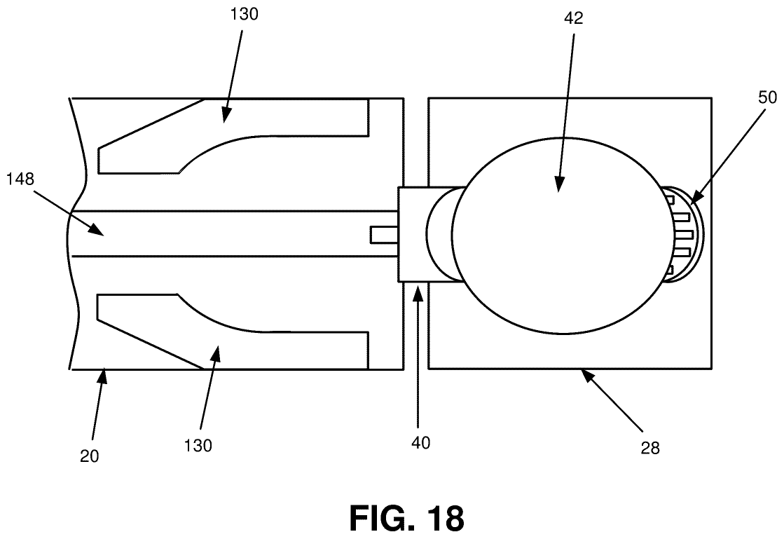

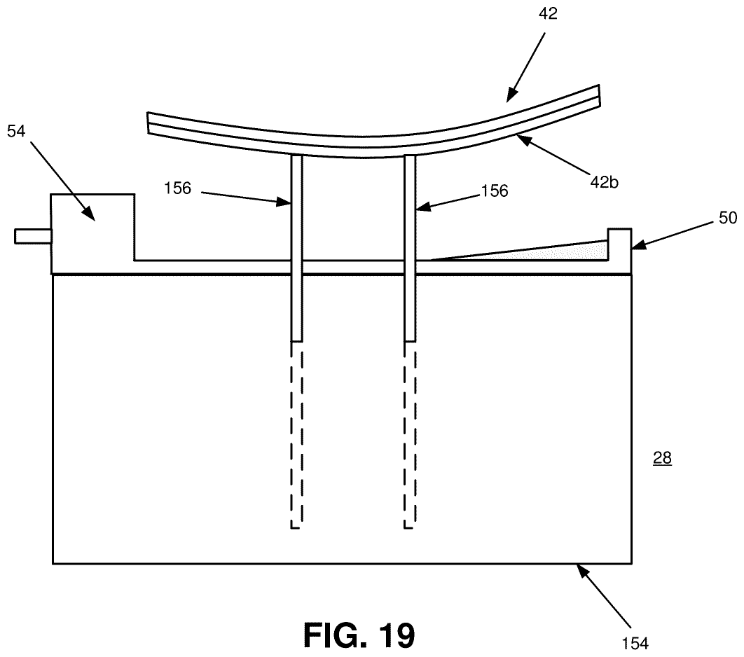

Referring now to FIGS. 18 and 19, the wafer transfer blade 50 may be moved from the retracted position to an extended position in order to move a wafer 42 into a chamber 28. In some embodiments, the wafer 42 may be moved by the wafer transfer blade 50 onto a wafer holder 154 in the chamber 28. The wafer holder 154 may include lift pins 156 that may be raised and lowered. When the wafer transfer tool 40 enters the chamber 28 and positions the wafer transfer blade 50 on the wafer holder 154, the openings 70 in the wafer transfer blade 50 are aligned over the lift pins 156. The lift pins 156 may then be raised to extend through the openings 70 in the wafer transfer blade 50 and into contact with the bottom surface 42b of the wafer 42, thereby lifting the wafer 42 from the wafer transfer blade 50. A transfer mechanism may then move the lifted wafer 42 to an area in the chamber 28, where a process is performed on the wafer 42. Once the process is completed, the wafer transfer blade 50 (which may have remained in the chamber 28 or may have left and returned to the chamber 28) is positioned on the wafer holder 154 and the transfer mechanism may return the processed wafer 42 to above the wafer transfer blade 50 and then lower the wafer 42 onto the wafer transfer blade 50, which is then moved out of the chamber 28.

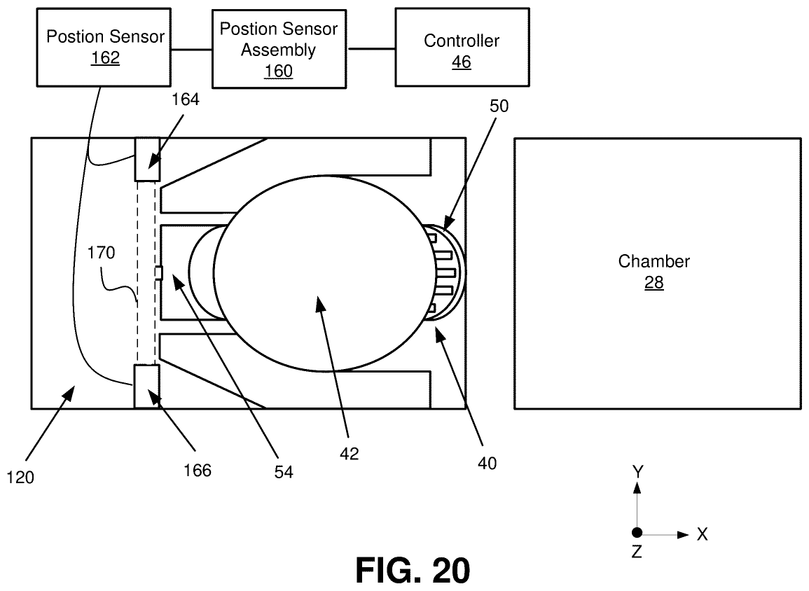

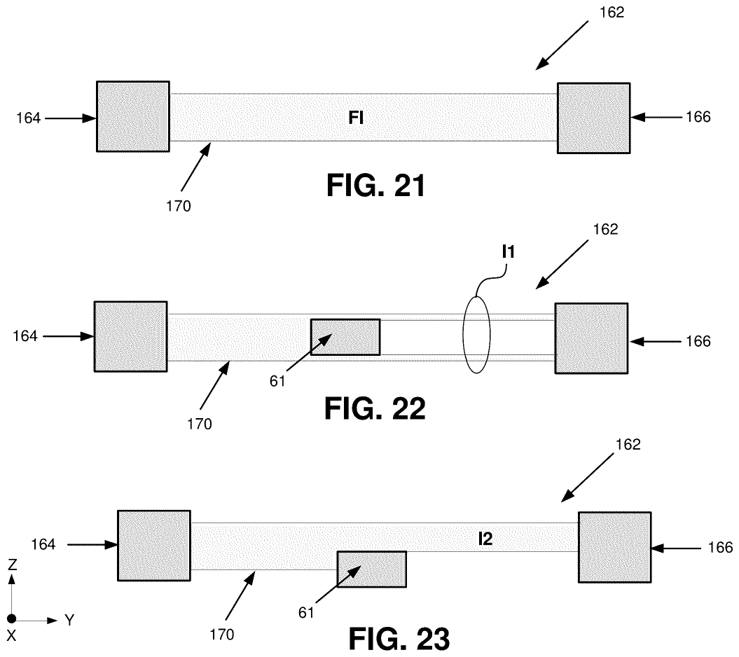

In some embodiments, before or during the travel of the wafer transfer blade 50 from the retracted position, the position of the wafer transfer tool 40 on the table 120 may be determined using a position sensor assembly 160, as shown in FIG. 20. For example, the position sensor assembly 160 may be used to determine if the wafer transfer blade 50 is correctly positioned to move a wafer 42 to a chamber 28 so as to not damage the wafer 42 or other wafers located in the chamber 28. The position sensor assembly 160 may include one or more position sensors 162 mounted to the table 120 and/or the wafer guides 130. Each position sensor 162 may be a through-beam type of sensor having an emitter 164 and a receiver 166. The emitter 164 may be configured to generate a light beam 170, and the receiver 166 may be configured to receive and process the light beam 170. When the light beam 170 travels unimpeded from the emitter 164 to the receiver 166 (e.g., is not blocked in any manner), the light received by the receiver 166 may have a full intensity FI, as shown in FIG. 21.

The emitter 164 may emit infrared light, visible light, ultraviolet light, light pulses or laser light. The emitter 164 may provide a single wavelength of light, multiple wavelengths of light, or a range of wavelengths of light (e.g., a spectrum). The emitter 164 may include a laser or an LED. In some embodiments, the emitter 164 may emit infrared light or visible light. The receiver 166 may include any suitable light detector configured to measure light intensity. For example, the receiver 166 may include a photoconductor, a photodiode, a phototransistor, a phototube, and/or the like.

Each of the position sensors 162 may be arranged such that the emitter 164 and the receiver 166 are disposed on opposite sides of the wafer transfer blade 50 such that the light beam 170 passing therebetween intersects the bar 61 extending from the rear structure 54 when the wafer transfer blade 50 is in the retracted position or is moving toward the extended position. The light beam 170 has a height (diameter) that is larger than a height (thickness) of the bar 61 in the Z-direction. When the wafer transfer blade 50 is properly oriented for movement to the extended position to deposit or retrieve a wafer 42 into or from a chamber 28, the bar 61 is in a normal position. As shown in FIG. 22, when the bar 61 is in the normal position, the height of the bar 61 may be centered along the height of the light beam 170 in the Z-direction, and the width of the bar 61 may be parallel to the light beam 170. When the bar 61 is in the normal position, the bar 61 will block a portion of the light beam 170, which causes the light received by the receiver 166 to have a normal intensity 11 that is less than the full intensity FI. If the bar 61 is not in the normal position, however, the light received by the receiver 166 will not have the normal intensity I1 or the full intensity FI, but will usually have an intensity in-between. For example, as shown in FIG. 23, a portion of the bar 61 may be outside the light beam 170, which will which cause the light received by the receiver 166 to have an intensity 12 that is greater than the normal intensity 11, but less than the full intensity FI.

The receiver 166 may generate a voltage based on the intensity of light received by the receiver 166. The voltage may be representative of the light intensity, e.g., the voltage increases with an increase in intensity. The receiver 166 may generate sensor signals that are representative of the voltage and, thus, light intensity. The sensor signals may be analog signals or digital signals and may be transmitted to a controller of the position sensor assembly 160 and thence to the controller 46 and/or may be sent directly to the controller 46.

The position sensor assembly 160 may be connected to the controller 46, which may perform a routine to control the transfer module 32 to move a wafer 42 to a chamber 28 for processing. As a part of this routine, the controller 46 may initially confirm that the wafer transfer blade 50 is correctly positioned in the retracted position to move the wafer 42 to the chamber 28. This confirmation may be performed using sensor signals from a position sensor 162 to determine whether the bar 61 is in the normal position when the wafer transfer blade 50 is in the retracted position. If the position sensor 162 confirms that the bar 61 is in the normal position, the controller 46 will continue to perform the routine and will instruct the linear actuator 150 to move the wafer transfer blade 50 toward the extended position. If, however, the position sensor 162 indicates that the wafer transfer blade 50 is not in the normal position, the controller 46 will stop the routine and prevent the wafer transfer blade 50 from being moved toward the extended position, until adjustments are made to have the wafer transfer blade 50 in the normal position.

In some embodiments, the position sensor assembly 160 may have a plurality of position sensors 162 arranged along the path of the wafer transfer blade 50 as the wafer transfer blade 50 travels along the table 120, toward its extended position. In some embodiments, the bar 61 may extend from a mount on a top surface of the rear structure 54 and one or more position sensors 162 are mounted on top of the wafer guides 130. The routine performed to control the transfer module 32 to move a wafer 42 to a chamber 28 for processing may be stopped at any point of the travel of the wafer transfer blade 50 if one of the position sensors 162 indicates that the bar 61 is not in the normal position.

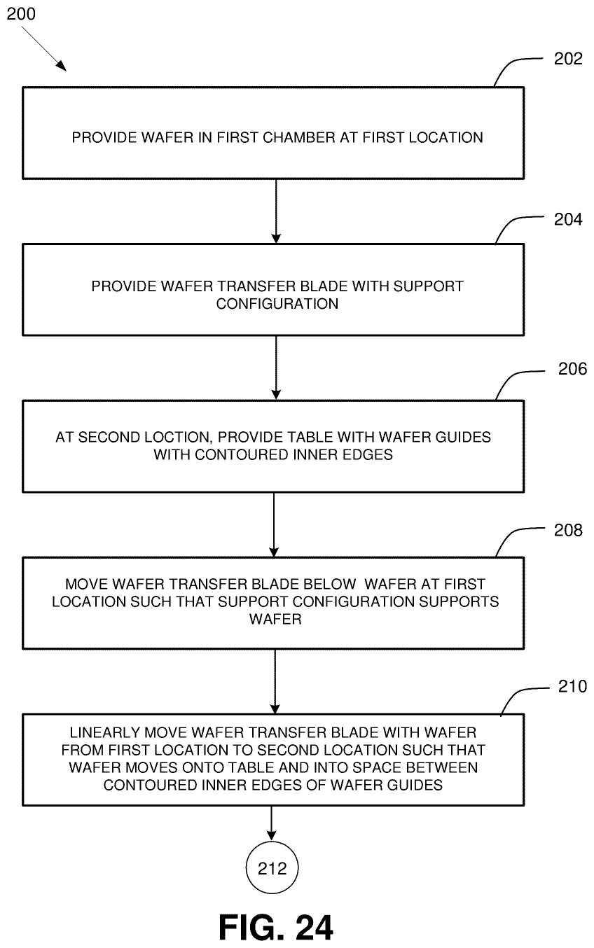

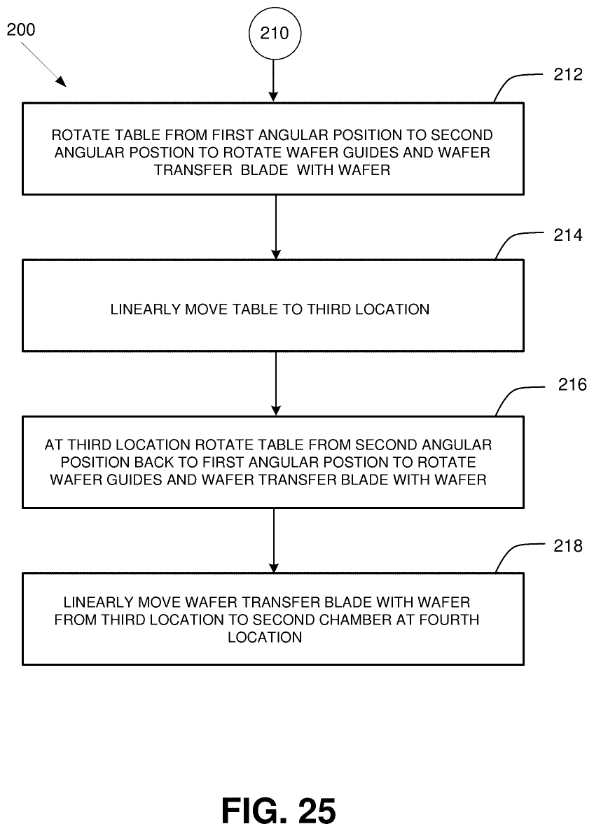

Referring now to FIGS. 24, 25, a method 200 of moving the wafer 42 may be performed in accordance with some embodiments. The method 200 may be performed, at least in part, using the transfer module 32 with the wafer transfer blade 50 connected thereto. At 202, a wafer 42 may be provided at a first location in a slot in a carrier 18 in the transfer chamber 28a. At 204, the wafer transfer blade 50 may be provided so as to be supported on the table 120 in the retracted position and not supporting a wafer 42. At 206, the table 120 is provided so as to be at a second location, aligned in the Y-direction and the Z-direction with the transfer chamber 28a. The wafer guides 130 are secured to the table 120 and form the holding space 144. At 208, the wafer transfer blade 50 may be moved to the extended position, where the wafer transfer blade 50 is positioned below the wafer 42 in the transfer chamber 28a so that the support configuration 66 of the wafer transfer blade 50 supports the bottom surface 42b of the wafer 42. At 210, the wafer transfer blade 50 may be moved back to the retracted position on the table 120, whereby the wafer 42 moves into the holding space 144 between the wafer guides 130 and engages the contoured inner edges 138, thereby causing the wafer 42 to be placed in a stable position on the support configuration 66 of the wafer transfer blade 50. At 212, the table 120 may be rotated clockwise about 90° from a first angular position to a second angular position, thereby rotating the wafer guides 130 and the wafer transfer blade 50 with the wafer 42 being held between the wafer guides 130 during the rotation. At 214, the table 120 may be linearly moved in the Y-direction to a third location aligned in the Y-direction and the Z-direction with another chamber 28. At 216, the table 120 at the third location may be rotated counterclockwise about 90° back to the first angular position such that the wafer 42 faces the other chamber 28 and is aligned with the other chamber 28 in the X-direction. At 218, the wafer transfer blade 50 may be moved to the extended position to place the wafer 42 in the other transfer chamber 28, which is at a fourth location.

According to some embodiments, a wafer transfer blade is provided. The wafer transfer blade has a bottom exterior and a top exterior opposite the bottom exterior. The bottom exterior has a support configuration disposed between a front structure and a rear structure that extend above the support configuration. The support configuration has a front portion adjoining the front structure and a rear portion adjoining the rear structure. The rear portion has a slide having a top surface that extends downwardly from a front joint located toward the front structure to a rear joint located toward the rear structure.

According to some embodiments, an assembly for moving a wafer is provided. The assembly has a wafer transfer blade and an apparatus for moving the wafer transfer blade. The wafer transfer blade has a bottom exterior and a top exterior opposite the bottom exterior. The bottom exterior has a support configuration disposed between a front structure and a rear structure. The support configuration has a front portion adjoining the front structure and a rear portion adjoining the rear structure. The rear portion has a slide having a top surface upon which the wafer sits and that extends downwardly from a front joint located toward the front structure to a rear joint located toward the rear structure. The apparatus for moving the wafer transfer blade has a table, an actuator for moving the wafer transfer blade relative to the table between a retracted position and an extended position, a first wafer guide secured to the table and having a first contoured inner edge with a first radius of curvature, and a second wafer guide secured to the table and having a second contoured inner edge with a second radius of curvature, wherein the first contoured inner edge faces the second contoured inner edge, a holding space is defined between the first contoured inner edge and the second contoured inner edge and is dimensioned as a function of the first radius of curvature and the second radius of curvature, and when the wafer transfer blade is in the retracted position at least some of the support configuration is disposed in the holding space.

According to some embodiments, a method of moving a wafer is provided. The method includes providing a wafer at a first location, providing a wafer transfer blade having a support configuration disposed between a front structure and a rear structure, wherein the support configuration has a slide having a top surface that extends downwardly with a non-linear slope from the front structure to the rear structure, providing a table at a second location, wherein a first wafer guide is attached to the table and a second wafer guide is attached to the table, wherein the first wafer guide has a first contoured inner edge and the second wafer guide has a second contoured inner edge, wherein a holding space is defined between the first contoured inner edge and the second contoured inner edge, moving the wafer transfer blade below the wafer at the first location such that the support configuration supports the wafer with the top surface of the slide contacting a bottom surface of the wafer, moving the wafer transfer blade with the wafer from the first location to the table at the second location such that the wafer is disposed in the holding space and the first contoured inner edge and the second contoured inner edge engage the wafer, and rotating the table from a first angular position to a second angular position.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

Although the subject matter has been described in language specific to structural features or methodological acts, it is to be understood that the subject matter of the appended claims is not necessarily limited to the specific features or acts described above. Rather, the specific features and acts described above are disclosed as example forms of implementing at least some of the claims.

Various operations of embodiments are provided herein. The order in which some or all of the operations are described should not be construed to imply that these operations are necessarily order dependent. Alternative ordering will be appreciated having the benefit of this description. Further, it will be understood that not all operations are necessarily present in each embodiment provided herein. Also, it will be understood that not all operations are necessary in some embodiments.

Moreover, “exemplary” is used herein to mean serving as an example, instance, illustration, etc., and not necessarily as advantageous. As used in this application, “or” is intended to mean an inclusive “or” rather than an exclusive “or”. In addition, “a” and “an” as used in this application and the appended claims are generally be construed to mean “one or more” unless specified otherwise or clear from context to be directed to a singular form. Also, at least one of A and B and/or the like generally means A or B or both A and B. Furthermore, to the extent that “includes”, “having”, “has”, “with”, or variants thereof are used, such terms are intended to be inclusive in a manner similar to the term “comprising”. Also, unless specified otherwise, “first,” “second,” or the like are not intended to imply a temporal aspect, a spatial aspect, an ordering, etc. Rather, such terms are merely used as identifiers, names, etc. for features, elements, items, etc. For example, a first element and a second element generally correspond to element A and element B or two different or two identical elements or the same element.

Also, although the disclosure has been shown and described with respect to one or more implementations, equivalent alterations and modifications will occur to others of ordinary skill in the art based upon a reading and understanding of this specification and the annexed drawings. The disclosure comprises all such modifications and alterations and is limited only by the scope of the following claims. In particular regard to the various functions performed by the above described components (e.g., elements, resources, etc.), the terms used to describe such components are intended to correspond, unless otherwise indicated, to any component which performs the specified function of the described component (e.g., that is functionally equivalent), even though not structurally equivalent to the disclosed structure. In addition, while a particular feature of the disclosure may have been disclosed with respect to only one of several implementations, such feature may be combined with one or more other features of the other implementations as may be desired and advantageous for any given or particular application.

What is claimed is:

1. A wafer transfer blade, comprising:
a bottom exterior; and
a top exterior opposite the bottom exterior comprising:
a support configuration disposed between a front structure and a rear structure that extend above the support configuration, the support configuration comprising:
a front portion adjoining the front structure; and
a rear portion adjoining the rear structure, wherein:
the rear portion comprises a slide having a top surface that extends downwardly from a front joint located toward the front structure to a rear joint located toward the rear structure.

2. The wafer transfer blade of claim 1, wherein the top surface of the slide is curved.

3. The wafer transfer blade of claim 1, wherein the top surface of the slide has a non-uniform slope.

4. The wafer transfer blade of claim 1, comprising a second slide having a top surface that extends downwardly in a direction from the front structure toward the rear structure.

5. The wafer transfer blade of claim 4, wherein the top surface of the slide has a first surface profile and the top surface of the second slide has a second surface profile matching the first surface profile.

6. The wafer transfer blade of claim 1, wherein the top surface of the slide abuts a bottom of the slide at an acute angle proximate the rear joint.

7. The wafer transfer blade of claim 6, wherein the top surface of the slide abuts an end of the slide proximate the front joint.

8. The wafer transfer blade of claim 7, wherein the bottom of the slide abuts the end of the slide at a right angle.

9. The wafer transfer blade of claim 1, comprising a planar support surface disposed between the front structure and the rear structure, wherein the slide is joined to the planar support surface.

10. The wafer transfer blade of claim 1, comprising a planar support surface disposed between the front structure and the rear structure, wherein a bottom of the slide is planar and coplanar with the planar support surface.

11. The wafer transfer blade of claim 1, wherein the slide comprises at least one of a metal, a ceramic, or a polymer.

12. An assembly for moving a wafer, comprising:
a wafer transfer blade comprising:
a bottom exterior; and
a top exterior opposite the bottom exterior comprising:
a support configuration disposed between a front structure and a rear structure, comprising:
a front portion adjoining the front structure; and
a rear portion adjoining the rear structure, wherein:
the rear portion comprises a slide having a top surface upon which the wafer sits and that extends downwardly from a front joint located toward the front structure to a rear joint located toward the rear structure; and
an apparatus for moving the wafer transfer blade, comprising:
a table;
an actuator for moving the wafer transfer blade relative to the table between a retracted position and an extended position;
a first wafer guide secured to the table and having a first contoured inner edge with a first radius of curvature; and
a second wafer guide secured to the table and having a second contoured inner edge with a second radius of curvature, wherein:
the first contoured inner edge faces the second contoured inner edge;
a holding space is defined between the first contoured inner edge and the second contoured inner edge and is dimensioned as a function of the first radius of curvature and the second radius of curvature; and
when the wafer transfer blade is in the retracted position, at least some of the support configuration is disposed in the holding space.

13. The assembly of claim 12, comprising:
a position sensor; and
a controller configured to determine a position of the wafer transfer blade based on a reading from the position sensor.

14. The assembly of claim 13, wherein:
the position sensor comprises an emitter and a receiver; and
the controller is configured to determine the position of the wafer transfer blade based on an amount of light emitted by the emitter that is received by the receiver.

15. The assembly of claim 14, wherein an amount of light blocked by the wafer transfer blade that is emitted by the emitter is a function of the position of the wafer transfer blade.

16. The assembly of claim 12, wherein the top surface of the slide is non-planar.

17. The assembly of claim 12, wherein the table is rotatable and movable in one or more linear directions.

18. The assembly of claim 12, wherein the wafer transfer blade comprises polytetrafluoroethylene.

19. A method of moving a wafer, comprising:
providing a wafer at a first location;
providing a wafer transfer blade having a support configuration disposed between a front structure and a rear structure, the support configuration comprising a slide having a top surface that extends downwardly with a non-linear slope from the front structure to the rear structure;
providing a table at a second location, wherein a first wafer guide is attached to the table and a second wafer guide is attached to the table, wherein the first wafer guide has a first contoured inner edge and the second wafer guide has a second contoured inner edge, wherein a holding space is defined between the first contoured inner edge and the second contoured inner edge;
moving the wafer transfer blade below the wafer at the first location such that the support configuration supports the wafer with the top surface of the slide contacting a bottom surface of the wafer;
moving the wafer transfer blade with the wafer from the first location to the table at the second location such that the wafer is disposed in the holding space and the first contoured inner edge and the second contoured inner edge engage the wafer; and
rotating the table from a first angular position to a second angular position.

20. The method of claim 19, comprising:
moving the table to a third location;
at the third location, rotating the table from the second angular position the first angular position; and
moving the wafer transfer blade with the wafer from the third location to a fourth location.
